(19) United States
(12) Patent Application Publication
(10) Pub. No.: US 2007/0008683 A1
(43) Pub. Date: Jan. 11, 2007

(54) Sealed tape storage apparatus

(76) Inventors: Stephan E. Gavit, Littleton, CO (US); Sharon Richardson, Littleton, CO (US); Donald Weinstock, Littleton, CO (US)

Correspondence Address: MARTIN & HENSON, P.C., 9250 W 5TH AVENUE, SUITE 200, LAKEWOOD, CO, 80226, US

(21) Appl. No.: 11/318,259

(22) Filed: Dec. 23, 2005

Related U.S. Application Data
(60) Provisional application No. 60/638,476, filed on Dec. 23, 2004.

(51) Int. Cl. H05K 5/00; B65D 6/28; B65D 85/00; B65D 8/18; H05K 7/00

(52) U.S. Cl. 361/679; 220/4.02; 206/807; 206/307

(57) ABSTRACT

A data storage apparatus includes at least one bearing member, a tape storage medium on first and second reels and a transducer all substantially sealed in a tamperproof housing. A drive mechanism is operative to rotate the reels to transport the tape storage medium therebetween across the bearing member so as to interface with the transducer. Electrical connectors are in communication with the interior of the housing and are accessible exteriorly of the housing to provide power and data access to the sealed components. The drive mechanism can be located either exteriorly or interiorly of the housing. The bearing member(s) can be air bearing(s). A heat dissipating structure may be secured to the exterior of the housing.

### FIELD OF THE INVENTION

The present invention is generally directed to a tape transport apparatus of the type employed in the data storage industry. More particularly, however, the present invention is directed to an enclosed and sealed combination tape drive and tape medium. Here, the drives, the tape medium, the tape transport structure and the read/write head are all parts of an integral unit that, in turn, may be mounted in a desired location.

### BACKGROUND OF THE INVENTION

The advent of the information age has seen an exponential growth in the accumulation and storage of data both for online usage as well as for archival purposes. In addition, many applications employ data storage systems for the recording of events occurring over a specified interval or event.

In the early days of the computer industry data was typically stored on magnetic tapes, such as reel-to-reel tapes and later cassettes that held spools of tape. The magnetic tape would be transported across a transducer, such as a magnetic coil, which would imprint or recall data from the moving band of magnetic film. Magnetic tape has an advantage that it is relatively low on cost and can be erased and rewritten many times. These systems were adequate where a low volume of data was to be retained. Following the development of tape storage, the use of magnetic disks was employed. Here, data was stored on a rotating flexible magnetic disk by a read/write head that was moved radially across the disk as the magnetic disk was rotated.

In addition to the magnetic media, other tape storage media have been developed or are possible. For example, data storage on optical media in the form of discs or tapes has been employed in an effort to increase the density of data stored on the medium. Optical media stores data according to the frequency of light of the transducer such that increased density is possible. Here, a laser device records and reads data. Due to the small wavelength of light, a greater density is obtained.

Regardless of the type of storage, the read/write apparatus typically accepted a removable storage medium. For example, cassettes containing the storage tape could be mounted and demounted from the read/write assembly so that individual cassettes could be stored and/or archived. Where either magnetic or optical discs are employed, the read/write assembly would mount and demount such disks. In this manner, a large number of discreet cassettes or disks could be employed with a single read/write assembly.

In many applications, the portability of the media that contains the data is desirable. For example, the use of easily transportable data storage media allows the access and use of data by read/write assemblies that are independent of each other. However, in some applications, it may not be desirable to have readily transportable media. Such applications, for example, include situations where the data may be of a sensitive nature. In such situations, the portability of the data may lead to its compromise. At the same time, portability under controlled circumstances may be needed.

In addition, the tolerances employed in the manufacture or either cassettes or discs due not allow for extremely high density of storage. Cassettes are usually made of plastic components that do not employ precision in manufacture, especially where numerous components need to be mated. The registration of cassettes and discs with the drive components also require some latitude resulting in lower tolerances. Where tape is employed, this can result in a significant amount of wobble and run-out. In either case, the presence of openings in the tape storage apparatus can allow dirt and debris to enter the interior, thus risking damage to the apparatus or to the storage media. All of these degrade the apparatus's ability to achieve a high data density. The present invention is directed to eliminating these issues and achieving high data storage capacity.

### SUMMARY OF THE INVENTION

It is an object of the present invention to provide a new and useful data storage apparatus.

Another object of the present invention is to provide a data storage apparatus wherein the storage medium is integral with the apparatus.

Yet another object of the present invention is to provide a date storage apparatus that is self contained and sealed.

Still further object of the present invention is to provide a portable data storage apparatus that can be mounted and removed from the system.

A still a further object of the present invention is to provide a data storage apparatus that increases the security of the date recorded therein.

These and other objects of the present invention will become more readily appreciated and understood from a consideration of the following detailed description of the exemplary embodiments of the present invention when taken together with the accompanying drawings, in which:

### BRIEF DESCRIPTION OF THE DRAWINGS

FIG. 1 is a perspective view, partially broken away, showing a data storage apparatus according to the exemplary embodiment of the present invention;

FIG. 2 is a perspective view of the data storage apparatus of FIG. 1 shown with its case in phantom;

FIG. 3 is a perspective view of the components of the data storage apparatus of FIGS. 1 and 2 shown on the mounting plate therefore;

FIG. 4 is a side view in cross-section of the data storage apparatus of FIG. 1; and

FIG. 5 is side view in cross-section showing an alternate embodiment of the data storage apparatus according to the present invention.

### DETAILED DESCRIPTION OF THE EXEMPLARY EMBODIMENTS

The present invention broadly concerns a data storage apparatus. More particularly, the present invention concerns a data storage apparatus including a storage medium contained therein as a sealed, tamperproof, and integral unit. According to the present invention, the apparatus may include internal electronics, or, alternatively, may be adapted to interface with the electronics that are exterior of the apparatus.

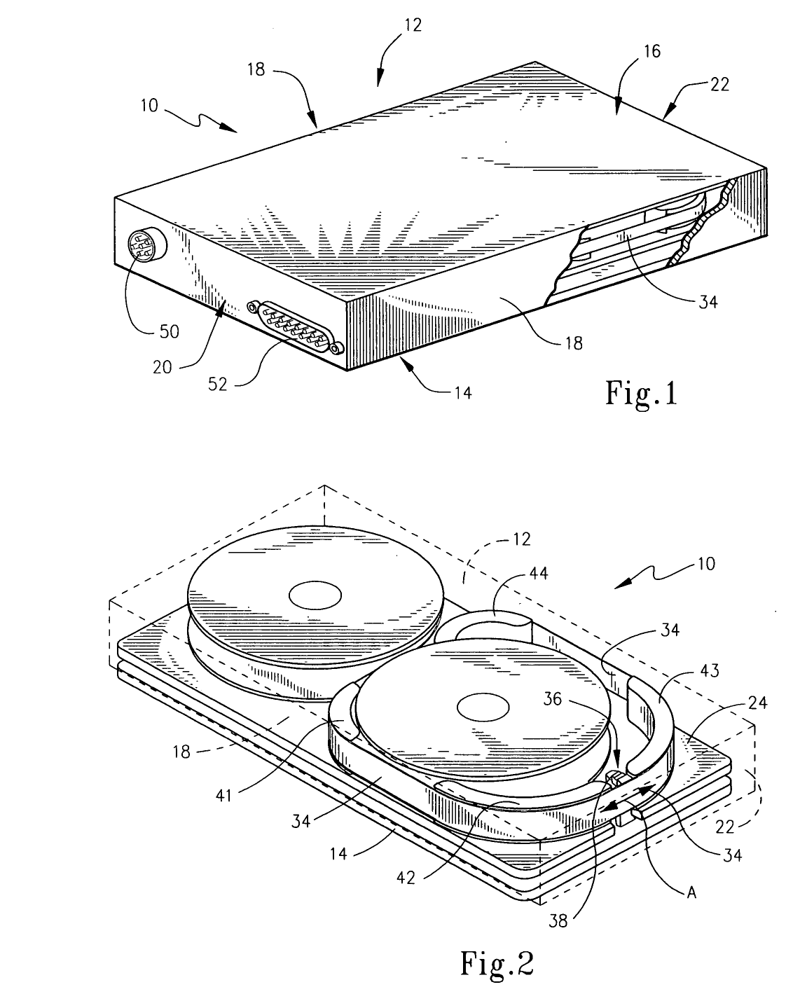

With reference, then, to FIGS. 1-4, a first exemplary embodiment of the present invention is illustrated as data storage apparatus 10. Data storage apparatus 10 includes an external housing 12 that has a bottom wall 14, a top wall 16, a pair of sidewalls 18, and end walls 20 and 22. A mounting plate 24 is disposed in the interior 26 of housing 12 and is positioned in parallel spaced-apart relation to bottom wall 14 by standoffs 28. Housing 12 and mounting plate 24 can be fabricated out of any suitable material, such as magnesium.

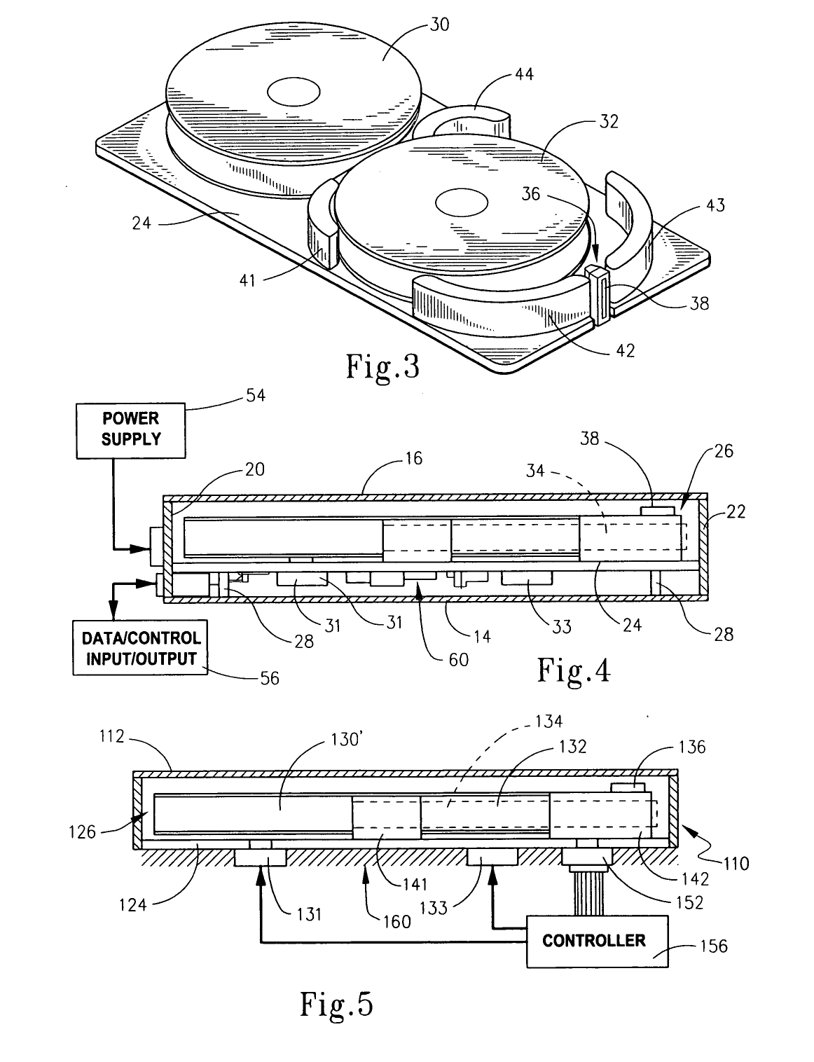

As best shown in FIG. 3, mounting plate 24 rotatably supports a supply reel 30 upon which is wrapped a suitable storage medium, such as an optical tape, a magnetic tape, or the like. Mounting plate 24 also rotatably supports a take up reel 32. Since there is no need to have mechanisms permitting the mounting and demounting of the tape, the physical dimensions of these reels 30 and 32 can be increased. For example, the reels may have a diameter of about five and one-half inches, and the tape width may conveniently be about ¾ inch. Where optical tape is used, this dimensioning can result in approximately 39,000 inches² of storage area compared to about 13.50 inches² for a standard optical disc.

Bearing members 41, 42, 43 and 44 define a tape transport path for media tape 34 (FIG. 2) so that tape 34 is supported for transport across bearings 41-44 and across a read/write recording region 36 wherein a transducer 38 is disposed. Tape 34 can be reciprocally driven across transport region 36 by means of a drive mechanism. A drive mechanism could include, for example, motors 31 and 33 that reversibly drive supply wheel 30 and take up wheel 32, respectively.

Bearings 41-44 can be of any type known in the art, but preferably employ single edge guiding, i.e., have a single datum, which helps reduce tape wobble and harmonics. Such bearings can be roller bearings, hydrodynamic surfaces, air bearings, etc. This would include pressurized air bearings of the type disclosed in U.S. Pat. No. 5,777,823 and U.S. Pat. No. 6,722,608, the disclosures of which are incorporated here in by reference.

An important aspect of the present invention is that the tape medium is permanently mounted in a tamperproof manner within the data storage apparatus 10. Making the housing 12 tamperproof would inhibit tampering and/or provide evidence of tampering. This does not mean, however, that the housing 12 is impregnable. Further, if desired, housing 12 not only completely encloses the components of data storage apparatus 10 but also can be hermetically sealed so as to prevent easy access to the tape medium 34 and to reduce the risk of ingress of dirt and contaminants. Accordingly, it is necessary to make suitable connections with the components located on the interior of housing 12.

Thus, as is illustrated in FIG. 1, a suitable power connector 50 is provided as well as a control and data connector 52. Connectors 50 and 52 may be of the type that includes connector pins with a surrounding housing. Power connector 52 thus may connect to a power source 54. A control and/or data connector 52 may connect to a suitable controller 56. This connection may be by way of fiber optics or more traditional electrical wiring. Controller 56 may interface with the electronics 60 that may be mounted to mounting plate 24 located in the interior 26 of housing 12 in order to allow data to be input to transducer 38 and thereafter imprinted on tape 34, or, allow data to be read from tape 34 by transducer 38 and output to the controller.

Transducer 38 can be any type of suitable transducer currently known in the art or hereinafter developed. Where the tape 34 is an optical tape, such would typically be any suitable laser read/write head. Where tape 34 is magnetic tape, the transducer would be any suitable electromagnetic head.

Where optical tape is employed, it is expected that the area and density for data storage, using high precision tape guides of the type referred to in the above-referenced patents and red lasers, data storage on the order of fourteen terabytes may be achieved. With blue laser transducers, the data storage could reach eighty terabytes.

The second exemplary embodiment of the present invention is illustrated in FIG. 5. Here, date storage apparatus 110 does not include electronic circuitry therein. Rather, housing 112 has an interior 126 that receives a supply reel 130 and a take up reel 132 as described above. Reels 130 and 132 are rotatably mounted to a mounting plate 124 that provides a bottom for housing 112. Suitable motor drives 131 and 133 are mounted exteriorly of housing 112. Bearings, such as bearings 141 and 142 provide a tape path for recording tape 134 (shown in phantom) that again is trained across a transducer 136. A controller 156 is used to provide power and control for motors 131 and 133 as well as to provide a data interface at control and data connector 152. In addition, as is illustrated in FIG. 5, a heat-dissipating array, such as heat sink 160 is provided to dissipate heat in the unit, if desired. It should be understood that a similar heat dissipation structure could be provided for in the embodiment shown in FIGS. 1-4, as well.

Accordingly, the present invention has been described with some degree of particularity directed to the exemplary embodiments of the present invention. It should be appreciated, though, that modifications or changes may be made to the exemplary embodiments of the present invention without departing from the inventive concepts contained herein.

I claim:

1. A data storage apparatus comprising:
a tamperproof housing including a top wall disposed in spaced-apart relation to a bottom wall with a surrounding sidewall extending therebetween to define an interior;
at least one bearing member disposed within the interior;
a tape storage medium disposed within the interior on first and second reels for transport therebetween;
a drive mechanism operative to rotate said first and second reels thereby to transport said tape therebetween across said bearing member along a tape transport path;
a transducer disposed within said interior proximately to the tape transport path and operative to interface with said tape storage medium for data communication therewith; and
electrical connectors supported by said housing and accessible exteriorly thereof and in electrical communication with the interior for providing power and data access thereto.

2. A data storage apparatus according to claim 1 wherein said drive mechanism is disposed in the interior of said housing.

3. A data storage apparatus according to claim 1 wherein said drive mechanism is secured to said housing exteriorly thereof.

4. A data storage apparatus according to claim 1 including a plurality of bearing members operative to support said tape medium along the tape transport path.

5. A data storage apparatus according to claim 4 wherein said bearing members are air bearings.

6. A data storage apparatus according to claim 1 including a heat dissipating structure secured to said housing exteriorly thereof.
